(19) United States
(12) Patent Application Publication
(10) Pub. No.: US 2008/0143904 A1
(43) Pub. Date: Jun. 19, 2008

(54) DISPLAY SUBSTRATE, METHOD OF MANUFACTURING THE SAME AND DISPLAY DEVICE HAVING THE SAME

(76) Inventors: Ji-Suk LIM, Daejeon (KR); Yong-Han Park, Anyang-si (KR)

Correspondence Address: Frank Chau, Esq.;F. CHAU & ASSOCIATES, LLC, 130 Woodbury Road, Woodbury, NY, 11797, US

(21) Appl. No.: 11/930,908

(22) Filed: Oct. 31, 2007

(30) Foreign Application Priority Data
Dec. 19, 2006 (KR) 2006-129808

(51) Int. Cl. G02F 1/1343; H01L 29/04; H01L 21/84

(52) U.S. Cl. 349/39; 257/59; 438/155; 257/E29.003; 257/E21.7

(57) ABSTRACT

A display substrate includes a substrate including a pixel area, a plurality of gate lines formed on the substrate, a plurality of data lines intersecting the plurality of gate lines, a storage capacitor formed adjacent the plurality of gate lines and the plurality of data lines to surround the pixel area, and a pixel electrode formed in the pixel area, the pixel electrode connected to the storage capacitor.

### CROSS-REFERENCE TO RELATED APPLICATION

The present application claims priority to Korean Patent Application No. 2006-129808, filed on Dec. 19, 2006, the disclosure of which is incorporated herein by reference.

### BACKGROUND OF THE INVENTION

1. Technical Field

The present disclosure relates to a display substrate, a method of manufacturing the display substrate, and a display device having the display substrate, and more particularly, to a display substrate capable of improving display quality.

2. Discussion of the Related Art

A liquid crystal display (LCD) device includes a thin film transistor (TFT) substrate, a countering substrate facing the TFT substrate and a liquid crystal layer interposed between the TFT substrate and the countering substrate. The TFT substrate includes a plurality of gate lines, a plurality of data lines, a switching element connected to the gate lines and the data lines and a pixel electrode connected to the switching element. The switching element includes a gate electrode extended from the gate lines, a channel overlapping the gate electrode, a source electrode, and a drain electrode. The source electrode is extended from the data lines and is electrically connected to the channel. The drain electrode is disposed opposite the source electrode with respect to the gate electrode and is electrically connected to the channel.

Masks for a photolithography process are used to manufacture the TFT substrate. When a number of the masks is reduced, manufacturing time and cost for the TFT substrate can be reduced.

### SUMMARY OF THE INVENTION

Exemplary embodiments of the present invention provide a display substrate capable of improving display quality and a method of manufacturing the display substrate, and a display device having the display substrate.

According to an exemplary embodiment of the present invention, a display substrate includes a substrate including a pixel area, a plurality of gate lines formed on the substrate, a plurality of data lines intersecting the plurality of gate lines, a storage capacitor formed adjacent to the plurality of gate lines and the plurality of data lines to surround the pixel area, and a pixel electrode formed in the pixel area, the pixel electrode connected to the storage capacitor.

The pixel electrode may contact the substrate.

The storage capacitor may include a storage common line including the same layer as the gate lines and formed adjacent the gate lines and the data lines to surround the edge of the pixel area, and a storage electrode overlapping the storage common line and connected to the pixel electrode.

The pixel area may include a switching element connected to the gate lines and the data lines.

The switching element may include a gate electrode extended from a gate line, a gate insulation layer to cover the gate electrode, a channel layer formed on the gate insulation layer to overlap the gate electrode, a source electrode extended from a data line, the source electrode formed on the channel layer, a drain electrode extended from the storage electrode, the drain electrode separated from the source electrode to expose the channel layer, and a passivation layer to cover the source electrode, the channel layer and the drain electrode.

The gate insulation layer and the channel layer can be formed between the storage common line and the storage electrode.

According to an exemplary embodiment of the present invention, a method of manufacturing a display substrate includes forming a gate line and a storage common line through a first photo-resist pattern on a substrate including a pixel area, the storage common line surrounding the pixel area, forming a data line intersecting the gate line and a storage electrode overlapping the storage common line through a second photo-resist pattern, and forming a pixel electrode in the pixel area through a third photo-resist pattern, an end portion of the pixel electrode connected to the storage electrode.

Forming the storage common line may include forming a gate metal layer on the substrate, forming the gate line, a gate electrode and the storage common line by patterning the gate metal layer through the first photo-resist pattern, and forming a gate insulation layer, a channel layer and a data metal layer on the patterned gate metal layer.

Forming the storage electrode may include forming the data line and the storage electrode by etching the data metal layer and the channel layer through the second photo-resist pattern, forming a first remaining pattern by removing a portion of the second photo-resist pattern, forming a source electrode, a drain electrode extended from the storage electrode and a channel portion by using the first remaining pattern as an etch mask, and forming a passivation layer on the source electrode, the drain electrode and the channel portion.

Forming the pixel electrode may include forming a photo-resist layer on the passivation layer, forming a third photo-resist pattern by patterning the photo-resist layer through a mask, exposing the substrate by etching the passivation layer and the gate insulation layer where the third photo-resist pattern is not formed, forming a second remaining pattern by removing a portion of the third photo-resist pattern, removing the passivation layer on the drain electrode and the storage electrode by using the second remaining pattern as an etch mask, forming a transparent conductive layer on the substrate where the drain electrode and the storage electrode are exposed, removing the second remaining pattern, and forming the pixel electrode by patterning the transparent conductive layer.

The mask may include a slit pattern corresponding to an area in which the storage electrode is formed.

According to an exemplary embodiment of the present invention, a display device includes a display substrate including a first substrate having a pixel area, a plurality of gate lines, a plurality of data lines, a storage capacitor surrounding the pixel area and a pixel electrode connected to the storage capacitor, and a countering substrate including a second substrate facing the first substrate and a color filter formed on the second substrate.

The display device may further include a liquid crystal layer interposed between the display substrate and the countering substrate.

The pixel electrode may contact the first substrate.

The countering substrate may further include a common electrode facing the pixel electrode.

The storage capacitor can be formed adjacent the gate lines and the data lines, and the storage capacitor blocks light leakage generated in an area adjacent the data lines.

The storage capacitor may include a storage common line including a same layer as the gate lines and formed adjacent the gate lines and the data lines to surround the edge of the pixel area, and a storage electrode overlapping the storage common line and connected to the pixel electrode.

The pixel area may comprise a switching element connected to the gate lines and the data lines.

The switching element may include a gate electrode extended from a gate line, a gate insulation layer to cover the gate electrode, a channel layer formed on the gate insulation layer to overlap the gate electrode, a source electrode extended from a data line, the source electrode formed on the channel layer, a drain electrode extended from the storage electrode, the drain electrode separated from the source electrode to expose the channel layer, and a passivation layer to cover the source electrode, the channel layer and the drain electrode.

The gate insulation layer and the channel layer can be formed between the storage common line and the storage electrode.

According to an exemplary embodiment of the present invention, a storage capacitor is formed to surround a pixel area through a three-mask process. Thus, an aperture ratio and capacitance of the storage capacitor is improved.

### BRIEF DESCRIPTION OF THE DRAWINGS

Exemplary embodiments of the present invention can be understood in more detail from the following descriptions taken in conjunction with the accompanying drawings, in which:

FIG. 1 is a plan view showing a display substrate according to an exemplary embodiment of the present invention;

FIG. 2 is a cross-sectional view taken along the line I-I′ of FIG. 1;

FIG. 3 is a plan view showing a first mask according to an exemplary embodiment of the present invention;

FIG. 4 is a cross-sectional view showing a display substrate formed by the first mask of FIG. 3;

FIG. 5 is a plan view showing a second mask according to an exemplary embodiment of the present invention;

FIGS. 6A to 6C are cross-sectional views showing a display substrate formed by the second mask of FIG. 5;

FIG. 7 is a plan view showing a third mask according to an exemplary embodiment of the present invention;

FIGS. 8A to 8D are cross-sectional views showing a display substrate formed by the third mask of FIG. 7; and

FIG. 9 is a plan view showing a display substrate according to an exemplary embodiment of the present invention.

### DESCRIPTION OF EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein.

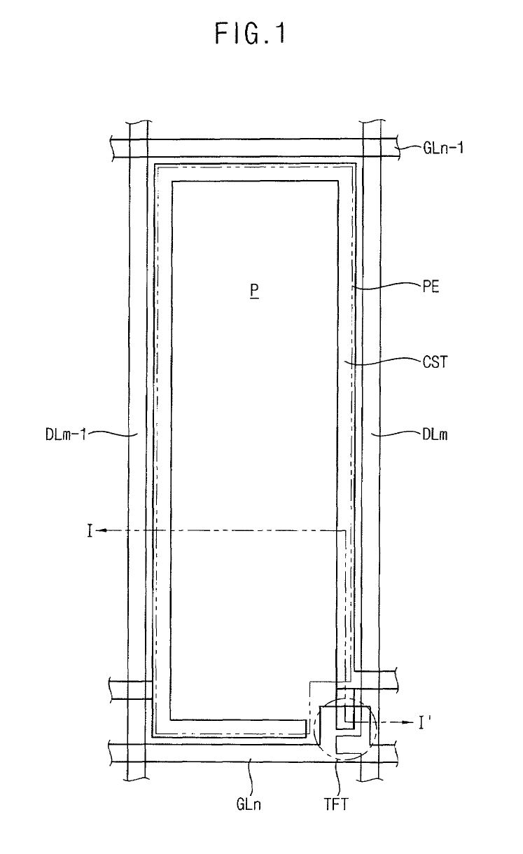

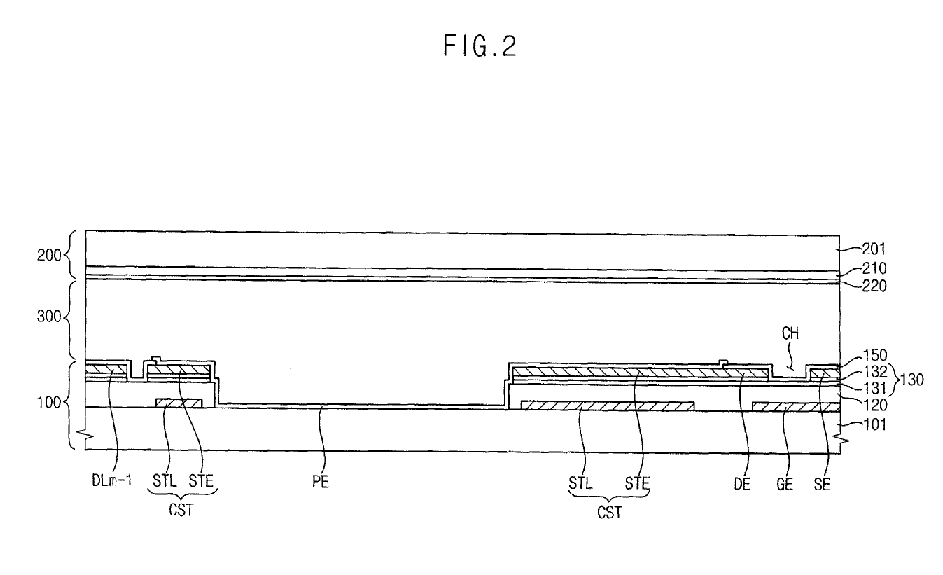

FIG. 1 is a plan view showing a display substrate according to an exemplary embodiment of the present invention. FIG. 2 is a cross-sectional view taken along the line I-I′ of FIG. 1.

Referring to FIGS. 1 to 2, a display device includes a display substrate 100, a countering substrate 200 facing the display substrate 100, and a liquid crystal layer 300 interposed between the display substrate 100 and the countering substrate 200.

The display substrate 100 includes a first base substrate 101. The first base substrate 101 includes a plurality of gate lines GLn-1, GLn, a plurality of data lines DLm-1, DLm1, a pixel area P, a thin film transistor switching element TFT, a storage capacitor CST and a pixel electrode PE.

The gate lines GLn-1, GLn are formed along a first direction, and the data lines DLm-1, DLm1 are formed along a second direction which intersects the first direction.

The pixel area P includes the switching element TFT, the storage capacitor CST and the pixel electrode PE. The storage capacitor CST is formed adjacent the gate lines GLn-1, GLn and the data lines DLm-1, DLm1 to surround the edge of the pixel area P. The storage capacitor CST is connected to the pixel electrode PE.

The switching element TFT may include a gate electrode GE extended from the gate line GLn, a source electrode SE extended from the data line DLm, and a drain electrode DE electrically connected to the pixel electrode PE. The drain electrode DE is extended from the storage capacitor CST and is separated from the source electrode SE.

A gate insulation layer 120 is formed on the gate electrode GE. A channel layer 130 is formed on the gate insulation layer 120 to overlap the gate electrode GE and is electrically connected to the source electrode SE and the drain electrode DE. The channel layer 130 includes an active layer 131 having amorphous silicon (a-Si) and an ohmic contact layer 132 doped with n+ impurities with a high concentration. A channel portion CH of the switching element TFT may be defined by the active layer 131 exposed between the source electrode SE and the drain electrode DE.

The storage capacitor CST may include a storage common line STL and a storage electrode STE. The storage common line STL is formed adjacent the gate lines GLn-1, GLn, and the data lines DLm-1, DLm to surround the edge of the pixel area P. Because the storage common line STL surrounds the edge of the pixel area P, an aperture ratio of the pixel area P can be improved as compared to the storage common line STL formed in the pixel area P independently. The storage electrode STE is extended from the drain electrode DE and overlaps the storage common line STL.

The storage common line STL may act as a light blocking member. When an arrangement of liquid crystal molecules adjacent to the data lines DLm-1, DLm is distributed by a data voltage applied to the data lines DLm-1, DLm, the storage common line STL blocks light leakage caused by the distributed liquid crystal molecules. Thus, display quality may be improved.

The gate insulation layer 120 is formed on the storage common line STL. The storage electrode STE is formed on the gate insulation layer 120 to overlap the storage common line STL. In an exemplary embodiment, the storage electrode STE may be formed from a same metal layer as that of the data lines DLm-1, DLm. The storage electrode STE may be in contact with the edge of the pixel electrode PE. The storage common line STL receives a common voltage, and the storage electrode STE receives a pixel voltage applied to the pixel electrode PE.

The pixel electrode PE includes a transparent conductive layer. The pixel electrode PE is connected to an end portion of the drain electrode DE and the storage electrode STE, and corresponds to the pixel area P. The pixel electrode PE may be in contact with the first base substrate 101.

The countering substrate 200 includes a second base substrate 201, a color filter 210 and a common electrode 220. The countering substrate 200 may further include a light blocking layer such as, for example, a black matrix, to define a transmission area in which light is passed through and a blocking area in which light is blocked.

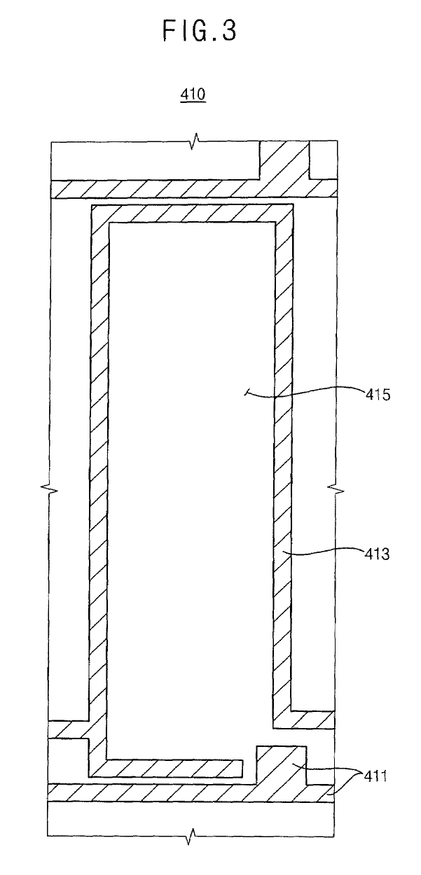

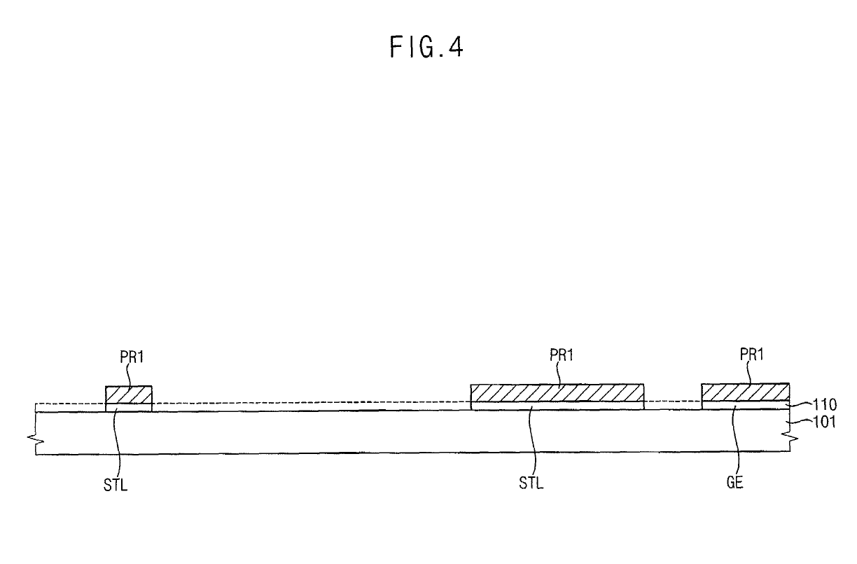

FIG. 3 is a plan view showing a first mask according to an exemplary embodiment of the present invention. FIG. 4 is a cross-sectional view showing a display substrate formed by the first mask of FIG. 3.

Referring to FIGS. 1, 3 and 4, a gate metal layer 110 is deposited on the base substrate 101. A first photo-resist layer is coated on the gate metal layer 110. The first photo-resist layer may include, for example, a positive type photo-resist layer or a negative type photo-resist layer. In the positive type photo-resist layer, a portion exposed by light remains during a developing process. In the negative type photo-resist layer, a portion exposed by light does not remain during a developing process.

The first photo-resist layer is patterned through a first mask 410. The first mask 410 includes a first light blocking pattern 411 corresponding to the gate electrode GE and the gate lines GLn-1, GLn, a second light blocking pattern 413 corresponding the storage common line STL, and a transmission portion 415 where the first and second light blocking pattern 411, 413 are not formed.

A first photo-resist pattern PR1 patterned through the first mask 410 is formed on the gate metal layer 110.

The gate metal layer 110 is patterned through the first photo-resist pattern PR1 so that a gate pattern including the gate lines GLn-1, GLn, the gate electrode GE and the storage common line STL is formed. The storage common line STL may surround the edge of the pixel area P. In an exemplary embodiment, the storage common line STL may be formed along the edge of the pixel area P.

The first photo-resist pattern PR1 can be removed through, for example, a stripping process.

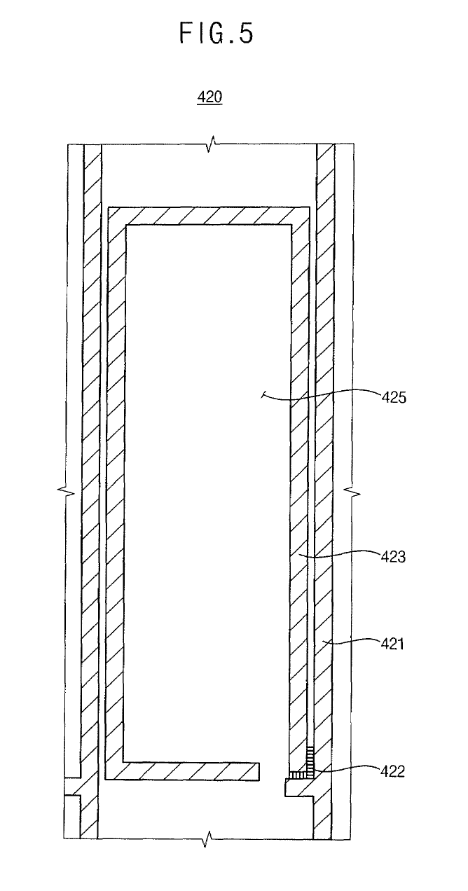

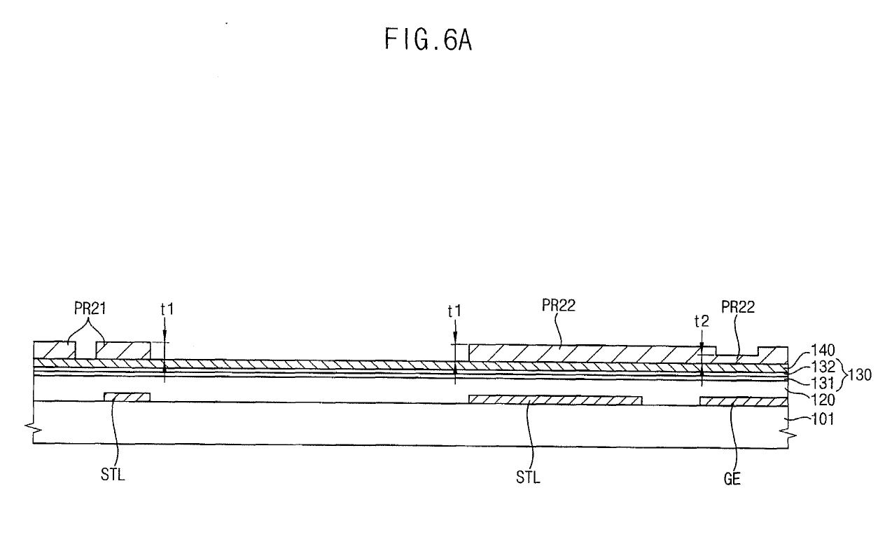

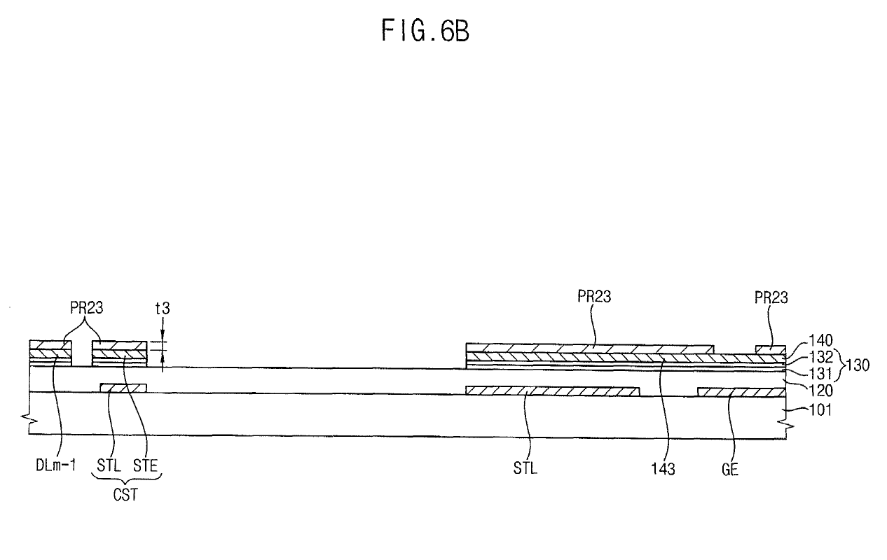

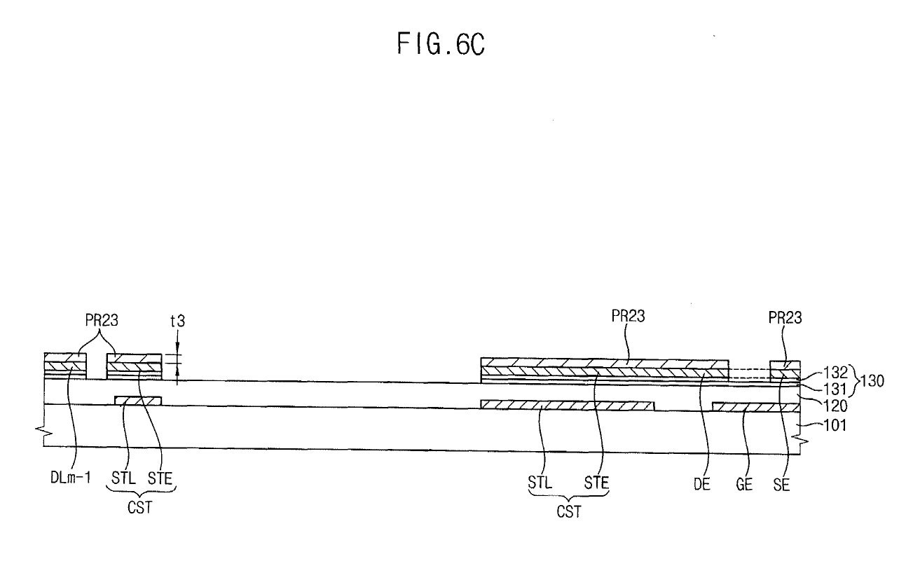

FIG. 5 is a plan view showing a second mask according to an exemplary embodiment of the present invention. FIGS. 6A to 6C are cross-sectional views showing a display substrate formed by the second mask of FIG. 5.

Referring to FIGS. 1, 5 and 6A, the gate insulation layer 120 is formed on the first base substrate 101 in which the gate pattern is formed.

The channel layer 130 is formed on the first base substrate 101 on which the gate insulation layer is formed. The channel layer 130 may include an active layer 131 having amorphous silicon (a-Si) and an ohmic contact layer 132 doped with n+ impurities at a high concentration. A data metal layer 140 is formed on the first base substrate 101 in which the channel layer 130 is formed.

A second photo-resist layer is coated on the data metal layer 140. The second photo-resist layer may be a positive type photo-resist layer. The second photo-resist layer is patterned through a second mask 420.

The second mask 420 may include a first light blocking pattern 421 corresponding to the source electrode SE, the drain electrode DE and the data lines DLm-1, DLm, a slit pattern 422 corresponding to the channel portion CH of the switching element TFT, a second light blocking pattern 423 corresponding to the storage electrode STE and a transmission portion 425.

A second photo-resist pattern patterned through the second mask 420 is formed on the data metal layer 140. The second photo-resist pattern may include a first photo pattern PR21 formed by the first and second light blocking patterns 421, 423 and having a first thickness t1 and a second photo pattern PR22 formed by the slit pattern 422 and having a second thickness t2 thinner than the first thickness t1.

Referring to FIGS. 1, 5 and 6B, a data pattern is formed by patterning the data metal layer 140 and the channel layer 130 through the first and second photo patterns PR21, PR22.

The data pattern may include the data lines DLm-1, DLm, the storage electrode STE and a data metal pattern 143. The data metal pattern 143 corresponds to the source electrode SE, the drain electrode DE and the channel portion CH.

Each thickness of the first and second photo patterns PR21, PR22 formed on the first base substrate 101 is reduced through an etch-back process. A first remaining pattern PR23 having a third thickness t3 is formed on the source electrode SE and the drain electrode DE through the etch-back process. The second photo pattern PR21 corresponding the channel portion CH is removed so that the data metal pattern 143 is exposed.

Referring to FIGS. 1, 5 and 6C, the source electrode SE and the drain electrode DE are formed by patterning the data metal pattern 143 through the first remaining pattern PR23. The active layer 131 is exposed by removing the exposed ohmic contact layer 132. Thus, the source electrode SE, the drain electrode DE and the channel portion CH of the switching element TFT are formed. The first remaining pattern PR23 can be removed through, for example, a stripping process.

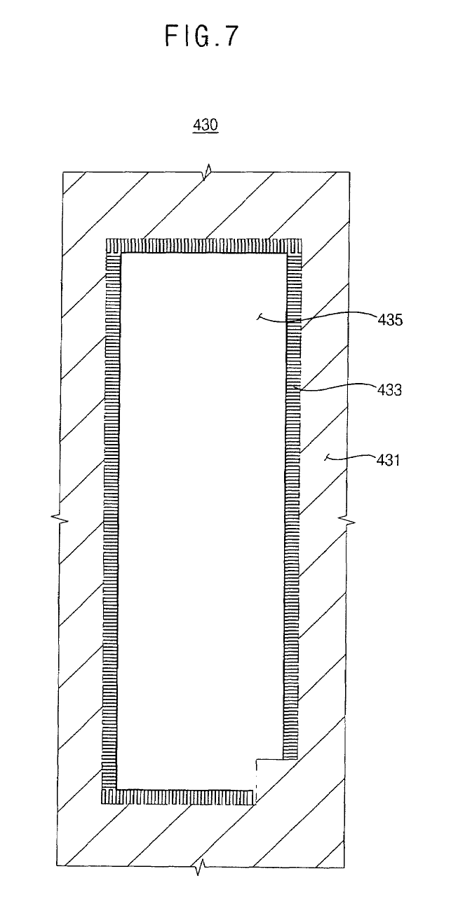

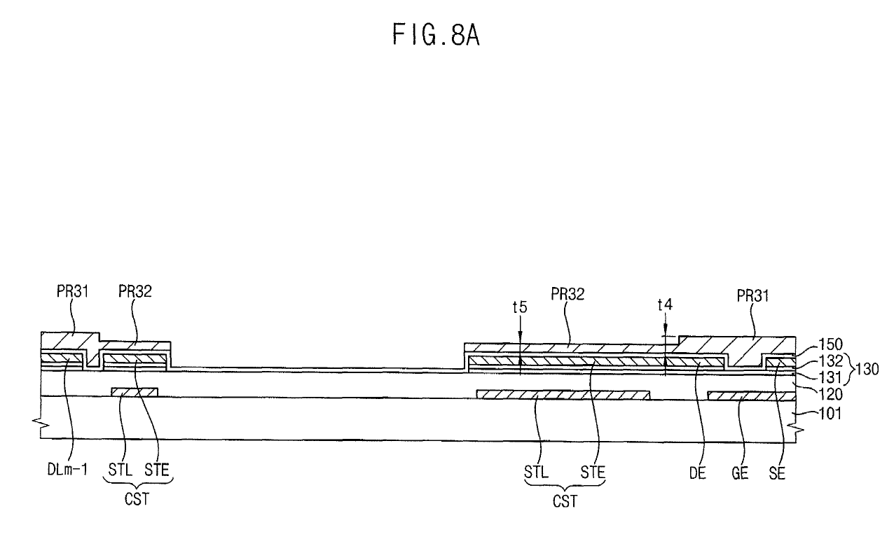

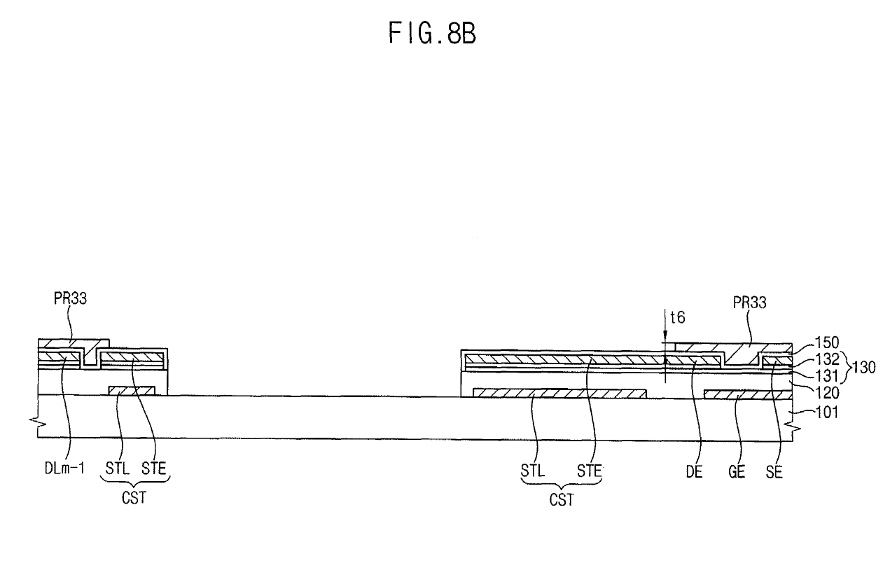

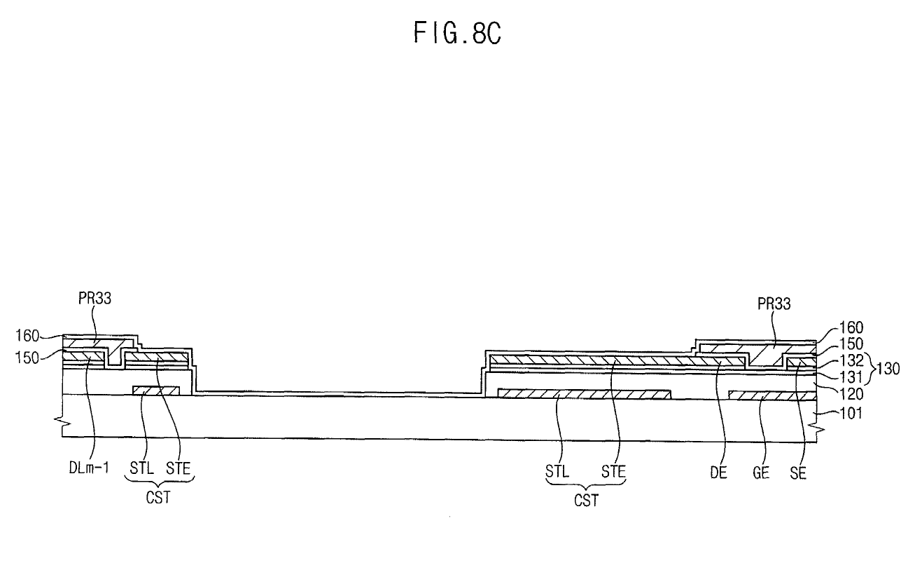

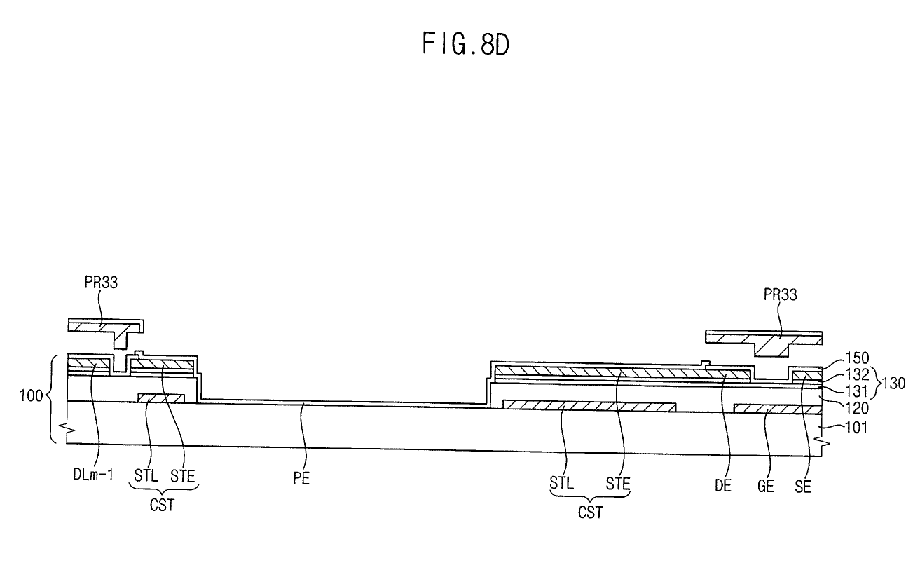

FIG. 7 is a plan view showing a third mask according to an exemplary embodiment of the present invention. FIGS. 8A to 8D are cross-sectional views showing a display substrate formed by the third mask of FIG. 7.

Referring to FIGS. 1, 7 and 8A, a passivation layer 150 is formed on the first base substrate 101 on which the switching element TFT is formed. A third photo-resist layer is formed on the first base substrate 101 on which the passivation layer 150 is formed.

The third photo-resist layer is patterned through a third mask 430. The third mask 430 may include a light blocking pattern 431 corresponding to the gate lines GLn-1, GLn, the data lines DLm-1, DLm and the switching element TFT, a slit pattern 433 corresponding to an end portion of the drain electrode DE, the storage electrode (or the storage common line) STE extended from the drain electrode DE, and a transmission portion 435 corresponding to the pixel electrode PE.

The light blocking pattern 431 of the third mask 430 corresponds to an area in which the gate and data metal layers are formed. The transmission portion 435 of the third mask 430 corresponds to the pixel electrode PE. The slit pattern 433 of the third mask 430 corresponds to an area in contact with the pixel electrode PE.

A third photo-resist pattern patterned through the third mask 430 is formed on the passivation layer 150. The third photo-resist pattern may include a third photo pattern PR31 and a fourth photo pattern PR32.

The third photo pattern PR31 is formed in an area corresponding to the gate lines GLn-1, GLn, the data lines DLm-1, DLm and the switching element TFT by the light blocking pattern 431. The third photo pattern PR31 has a first thickness t4. The fourth photo pattern PR32 is formed in an area corresponding to the end portion of the drain electrode DE and the storage electrode STE by the slit pattern 433. The fourth photo pattern PR32 has a second thickness t5 thinner than the first thickness t4.

Referring to FIGS. 1, 7 and 8B, the passivation layer 150 and the gate insulation layer 120 are removed by a first etching process through the third and fourth photo patterns PR31, PR32. The pixel area P of the first base substrate 101 is exposed by the first etching process.

Each thickness of the third and fourth photo patterns PR31, PR32 can be reduced by, for example, an etch-back process. The passivation layer 150 formed on the end portion of the drain electrode DE and the storage electrode STE is exposed by the etch-back process. A second remaining pattern PR33 remains on the switching element TFT and the data lines DLm-1, DLm. The second remaining pattern PR33 has a third thickness t6.

Referring to FIGS. 1, 7, 8B and 8D, the passivation layer 150 is removed by a second etching process through the second remaining pattern PR33. Thus, the end portion of the drain electrode DE and the storage electrode STE are exposed.

A transparent conductive layer 160 is formed on the first base substrate 101 on which the end portion of the drain electrode DE and the storage electrode STE are exposed. The transparent conductive layer 160 is in contact with the end portion of the drain electrode DE and the storage electrode STE. The transparent conductive layer 160 is in contact with the first base substrate 101 exposed by the first etching process.

The second remaining pattern PR33 can be removed through, for example, a stripping process. Thus, the transparent conductive layer 160 is patterned so that the pixel electrode PE in the pixel area P is formed. The pixel electrode PE is connected to the end portion of the drain electrode DE and the storage electrode STE, and is formed in the pixel area P.

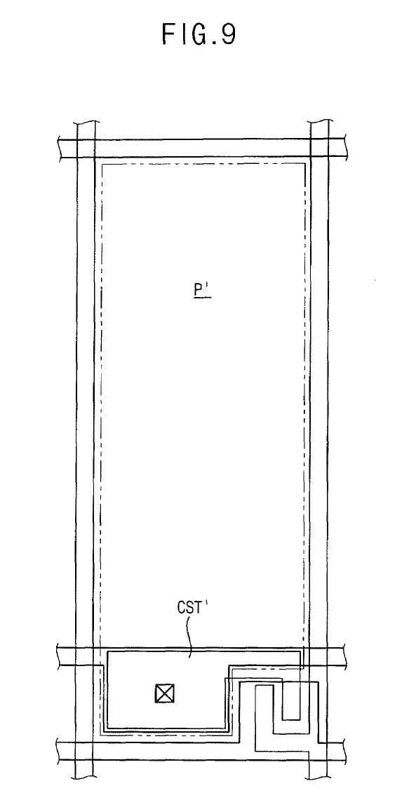

FIG. 9 is a plan view showing a display substrate according to an exemplary embodiment of the present invention.

Referring to FIGS. 1 to 8D, the storage capacitor CST surrounds the pixel area P. In FIG. 9, a storage capacitor CST′ formed in a pixel area P′ does not surround the pixel area P′.

Table 1 represents aperture ratios and capacitances of the storage capacitors CST and CST′.

TABLE 1

| | Comparative | Embodiment of | |
|---|---|---|---|
| | embodiment of FIG. 9 | FIG. 1 | Improvement |
| Aperture ratio | 53% | 59% | 6% |
| Capacitance | 120fF | 300fF | 250% |

Referring to Table 1, an aperture ratio of a comparative embodiment of FIG. 9 is about 53%. An aperture ratio of an embodiment of FIG. 1 is about 59%. Thus, the aperture ratio of the embodiment of FIG. 1 is improved by about 6%.

A capacitance of the storage capacitor CST′ of FIG. 9 is 120 fF. A capacitance of the storage capacitor CST of FIG. 1 is 300 fF. Thus, the capacitance of the storage capacitor CST of FIG. 1 is improved by about 250%.

Since the storage capacitor CST surrounds the pixel area P, the aperture ratio and the capacitance of the storage capacitor CST are improved.

Since the storage capacitor CST is formed adjacent to the gate lines and the data lines, the storage capacitor CST can block light leakage caused by a disclination of liquid crystal molecules when a voltage is applied to the lines. Thus, display quality can be improved.

According to an exemplary embodiment of the present invention, a storage capacitor is formed to surround a pixel area through a three-mask process. Thus, an aperture ratio and capacitance of the storage capacitor is improved.

Although the liquid crystal molecules adjacent to the data lines are distributed by a voltage applied to the data lines, the storage capacitor blocks the light leakage caused by the distributed liquid crystal molecules. Thus, display quality is improved.

Although the illustrative embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A display substrate comprising:
a substrate including a pixel area;
a plurality of gate lines formed on the substrate;
a plurality of data lines intersecting the plurality of gate lines;
a storage capacitor formed adjacent to the plurality of gate lines and the plurality of data lines to surround the pixel area; and
a pixel electrode formed in the pixel area, wherein the pixel electrode is connected to the storage capacitor.

2. The display substrate of claim 1, wherein the pixel electrode contacts the substrate.

3. The display substrate of claim 1, wherein the storage capacitor comprises:
a storage common line including the same layer as the gate lines and formed adjacent the gate lines and the data lines to surround the edge of the pixel area; and
a storage electrode overlapping the storage common line and connected to the pixel electrode.

4. The display substrate of claim 3, wherein the pixel area comprises a switching element connected to the gate lines and the data lines.

5. The display substrate of claim 4, wherein the switching element comprises:
a gate electrode extended from one of the gate lines;
a gate insulation layer covering the gate electrode;
a channel layer formed on the gate insulation layer overlapping the gate electrode;
a source electrode extended from one of the data lines, the source electrode formed on the channel layer;
a drain electrode extended from the storage electrode, the drain electrode separated from the source electrode to expose the channel layer; and
a passivation layer covering the source electrode, the channel layer and the drain electrode.

6. The display substrate of claim 5, wherein the gate insulation layer and the channel layer are formed between the storage common line and the storage electrode.

7. A method of manufacturing a display substrate, the method comprising:
forming a gate line and a storage common line through a first photo-resist pattern on a substrate including a pixel area, the storage common line surrounding the pixel area;
forming a data line intersecting the gate line and a storage electrode overlapping the storage common line through a second photo-resist pattern; and
forming a pixel electrode in the pixel area through a third photo-resist pattern, wherein an end portion of the pixel electrode is connected to the storage electrode.

8. The method of claim 7, wherein forming the storage common line comprises:
forming a gate metal layer on the substrate;
forming the gate line, a gate electrode and the storage common line by patterning the gate metal layer through the first photo-resist pattern; and
forming a gate insulation layer, a channel layer and a data metal layer on the patterned gate metal layer.

9. The method of claim 8, wherein forming the storage electrode comprises:
forming the data line and the storage electrode by etching the data metal layer and the channel layer through the second photo-resist pattern;
forming a first remaining pattern by removing a portion of the second photo-resist pattern;
forming a source electrode, a drain electrode extended from the storage electrode and a channel portion by using the first remaining pattern as an etch mask; and
forming a passivation layer on the source electrode, the drain electrode and the channel portion.

10. The method of claim 9, wherein forming the pixel electrode comprises:
forming a photo-resist layer on the passivation layer;
forming a third photo-resist pattern by patterning the photo-resist layer through a mask;
exposing the substrate by etching the passivation layer and the gate insulation layer where the third photo-resist pattern is not formed;
forming a second remaining pattern by removing a portion of the third photo-resist pattern;
removing the passivation layer on the drain electrode and the storage electrode by using the second remaining pattern as an etch mask;
forming a transparent conductive layer on the substrate where the drain electrode and the storage electrode are exposed;
removing the second remaining pattern; and
forming the pixel electrode by patterning the transparent conductive layer.

11. The method of claim 10, wherein the mask comprises a slit pattern corresponding to an area in which the storage electrode is formed.

12. A display device comprising:
a display substrate including a first substrate having a pixel area, a plurality of gate lines, a plurality of data lines, a storage capacitor surrounding the pixel area and a pixel electrode connected to the storage capacitor; and
a countering substrate including a second substrate facing the first substrate and a color filter formed on the second substrate.

13. The display device of claim 12, further comprising a liquid crystal layer interposed between the display substrate and the countering substrate.

14. The display device of claim 12, wherein the pixel electrode contacts the first substrate.

15. The display device of claim 12, wherein the countering substrate further comprises a common electrode facing the pixel electrode.

16. The display device of claim 12, wherein the storage capacitor is formed adjacent the gate lines and the data lines, and the storage capacitor blocks light leakage generated in an area adjacent the data lines.

17. The display device of claim 12, wherein the storage capacitor comprises:
a storage common line including a same layer as the gate lines and formed adjacent the gate lines and the data lines to surround the edge of the pixel area; and
a storage electrode overlapping the storage common line and connected to the pixel electrode.

18. The display device of claim 17, wherein the pixel area comprises a switching element connected to the gate lines and the data lines.

19. The display device of claim 18, wherein the switching element comprises:
a gate electrode extended from one of the gate lines;
a gate insulation layer covering the gate electrode;
a channel layer formed on the gate insulation layer overlapping the gate electrode;
a source electrode extended from one of the data lines, the source electrode formed on the channel layer;
a drain electrode extended from the storage electrode, the drain electrode separated from the source electrode to expose the channel layer; and
a passivation layer covering the source electrode, the channel layer and the drain electrode.

20. The display device of claim 19, wherein the gate insulation layer and the channel layer are formed between the storage common line and the storage electrode.
